(19) United States
(12) Patent Application Publication
(10) Pub. No.: US 2002/0197855 A1
(43) Pub. Date: Dec. 26, 2002

(54) Chemical mechanical polishing slurry and process for ruthenium films

(76) Inventors: Jae Hong Kim, Kyoungki-do (KR); Sang Ick Lee, Kyoungki-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 10/038,375

(22) Filed: Jan. 4, 2002

(30) Foreign Application Priority Data
Jun. 26, 2001 (KR) 2001-36599

(51) Int. Cl. H01L 21/4763

(52) U.S. Cl. 438/650

(57) ABSTRACT

A CMP slurry for ruthenium and a polishing process using the same. In a process technology below 0.1 μm, when a capacitor using a (Ba₁₋ₓSrₓ)TiO₃ film as a dielectric film is fabricated, the slurry is used to polish a ruthenium film deposited as a lower electrode according to a CMP process. The CMP process is performed by using the slurry, to improve a polishing speed of ruthenium under a low polishing pressure. In addition, the CMP process is performed according to an one-step process by using one kind of slurry. As a result, defects on an insulating film are reduced and a polishing property is improved, thereby simplifying the CMP process.

### TECHNICAL FIELD

A chemical mechanical polishing (abbreviated as ‘CMP’) slurry for ruthenium films, and a polishing process using the same are disclosed. In particular, a slurry used when a ruthenium film deposited as a lower electrode is polished with a CMP process in forming a capacitor using a (Ba₁₋ₓSrₓ)TiO₃ (abbreviated as ‘BST’) film as a dielectric film in a process technology below 0.1 μm, and a polishing process using the same are disclosed.

### BACKGROUND

Ruthenium is a precious metal which has excellent mechanical and chemical properties and which is essential to form a high performance capacitor. Ruthenium is deposited on a BST film which is a dielectric film. The ruthenium is used as a lower electrode. A CMP process can be employed to polish the ruthenium film.

CMP processes are used in planarization processes mostly used for semiconductor wafer manufacturing processes over 64M requiring high accuracy, and a typical CMP slurry comprises chemicals for planarizing various film, for example, an insulating film, metal layer, polysilicon and so on. In general, a slurry consists of a solvent, a chemical compound and an abrasive. A surfactant can be added in small amounts to improve the slurry properties.

The chemical compound and abrasive are used is dependent upon the kind of a film to be polished. For example, an alkali solution such as KOH or NH₄OH is used as a chemical compound for polishing an oxide film, and SiO₂ is commonly used as an abrasive for polishing the oxide film. An oxidizer such as hydrogen peroxide is used as a chemical compound for polishing a metal film, H₂SO₄, HNO₃ or HCl is added in a small volume to adjust the slurry to acidity, and Al₂O₃ is also used as an abrasive for polishing the metal film.

CMP processes are performed by combining a chemical reaction and a mechanical reaction. The chemical reaction implies a chemical reaction between the chemical compound contained in the slurry and the film being polished. In the mechanical reaction, a force applied by a polishing device is transmitted to the film already subjected to the chemical reaction and grinded by an abrasive to be removed.

More specifically, in the CMP process, a rotating polishing pad and a substrate are directly pressure-contacted, and the polishing slurry is provided as an interface thereof. Thus, the surface of the substrate is mechanically chemically polished and planarized by the polishing pad coated with the slurry. Accordingly, the polishing speed and erosion of the polished surface are varied due to a composition of the slurry.

Since an appropriate CMP slurry is not available for ruthenium so far, slurries for tungsten or aluminum are currently employed instead. In this case, the polishing speed of ruthenium is slow, and thus the CMP process is performed for a long time under a high polishing pressure. Therefore, scratches and impurities can be generated on the insulating film.

Ruthenium has poor adhesion to the insulating film. When ruthenium is polished for a long time under a high polishing pressure, ruthenium may be separated from the peripheral insulating film. In addition, dishing and erosion effects are generated on ruthenium adjacent to the insulating film, which result in deterioration of the properties of the device being manufacture.

Specifically, FIG. 1 is a cross-sectional diagram illustrating a semiconductor device including a capacitor where ruthenium is deposited as a lower electrode. A gate oxide film 2, a gate electrode 3 and a mask insulating film 4 are formed on a semiconductor substrate 1. An oxide film spacer 5 is formed at the side walls of the resultant structure. An interlayer insulating film 6 and silicon nitride 7 are formed over the resultant structure. A presumed capacitor contact region is removed according to a photolithography process, thereby forming a contact hole.

Thereafter, a stacked layers of polysilicon 8, TiSi₂ 9 and TiAlN 10 fills up the contact hole as a contact plug. A sacrificial insulating film is formed on the silicon nitride 7, and patterned. Accordingly, the contact plug is exposed to form a sacrificial insulating film pattern 11.

A ruthenium film 12 is formed on the sacrificial insulating film pattern 11, and a sacrificial photoresist film is coated on the whole surface of the ruthenium film 12. A sacrificial photoresist film pattern 13 is formed according to the above-identified CMP process using the ruthenium film 12 as an etch barrier film. The ruthenium film 12 is patterned according to the CMP process using the sacrificial insulating film pattern 11 as an etch barrier film, thereby forming a lower electrode

The patterning process is performed by polishing the sacrificial photoresist film and the ruthenium film 12 according to the CMP process in a predetermined polishing target line.

FIG. 2 is a cross-sectional diagram in a state where the CMP process has been performed on the ruthenium film of FIG. 1 by using a conventional slurry. The general conditions of the CMP process include a polishing pressure ranging from about 3 to about 5 psi, a table revolution number ranging from about 80 to about 100 rpm by a rotary type system, and a table movement speed ranging from about 600 to about 700 fpm by a linear type system.

However, the polishing speed of ruthenium is slow under the above general conditions, and thus the CMP process is, at best, only moderately successful. To increase the polishing speed of ruthenium, the amount of slurry and the polishing pressure should be increased.

However, as shown in FIG. 2, scratches 14 are generated on the sacrificial insulating film pattern 11 due to the high polishing pressure, impurities such as slurry residuals or particles 15 remain thereon, the ruthenium film 12 is polished more than the sacrificial insulating film from a time of exposing the sacrificial insulating film to cause a dishing phenomenon, and the peripheral sacrificial insulating film is seriously eroded. In addition, an excessive physical force is applied to the ruthenium film 12 having weak adhesion to the sacrificial insulating film, and thus the ruthenium film 12 deposited at the side walls of the sacrificial insulating film pattern 11 is deformed or separated from the sacrificial insulating film pattern 11.

Moreover, a slurry for the sacrificial insulating film is required to remove the scratches 14 and the particles 15 generated after the CMP process of the ruthenium film 12. That is, the ruthenium film 12 is polished in a first step, and the surface of the sacrificial insulating film pattern 11 is slightly polished by using a specific slurry in a second step, thereby preventing generation of the particles 15.

### SUMMARY OF THE DISCLOSURE

A CMP slurry and a CMP process using the same are disclosed which can improve the polishing speed of ruthenium under a low polishing pressure and polish ruthenium according to an one-step process by using a single slurry.

A method for manufacturing a semiconductor device according to a CMP process using a single slurry, and a semiconductor device manufactured according to the method are also disclosed.

In summary, a CMP slurry for ruthenium containing ceric ammonium nitrate [(NH₄)₂Ce(NO₃)₆], a CMP process using the same, a method for manufacturing a semiconductor device according to the CMP process using the slurry, and a semiconductor device manufactured according to the method are all disclosed.

### BRIEF DESCRIPTION OF THE DRAWINGS

The disclosure will become better understood with reference to the accompanying drawings which are given only by way of illustration and thus are not limitative of the disclosure, wherein:

FIG. 1 is a cross-sectional diagram illustrating a prior art semiconductor device including a capacitor where a ruthenium film is deposited as a lower electrode;

FIG. 2 is a cross-sectional diagram illustrating a semiconductor device where a ruthenium film is patterned by using a prior art slurry; and

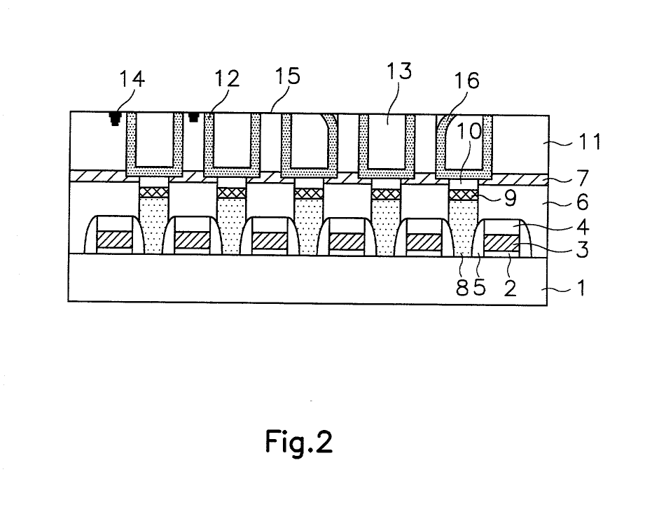

FIG. 3 is a cross-sectional diagram illustrating a semiconductor device where a ruthenium film is patterned by using a slurry in accordance with the disclosure.

### DETAILED DESCRIPTION OF THE PRESENTLY PREFERRED EMBODIMENTS

A CMP slurry for ruthenium containing ceric ammonium nitrate [(NH₄)₂Ce(NO₃)₆] includes distilled water, nitric acid (HNO₃), ceric ammonium nitrate and an abrasive. Preferably, HNO₃ is used in an amount ranging from about 1 to about 10% by weight of the slurry, ceric ammonium nitrate is used in an amount ranging from about 1 to about 10% by weight of the slurry, and the abrasive is used in an amount ranging from about 1 to about 5% by weight of the slurry.

Here, HNO₃ and ceric ammonium nitrate are used in an amount ranging from about 1 to about 10% by weight of the slurry, thereby stabilizing and easily handling the slurry.

HNO₃ maintains pH of the slurry from about 1 to about 7, preferably from about 1 to about 3 for strong acidity. H₂SO₄, HCl or H₃PO₄ may be used instead of HNO₃. However, HNO₃ is most efficient.

Ceric ammonium nitrate serves as an oxidizer for extracting electrons from ruthenium atoms.

The more HNO₃ and ceric ammonium nitrate are used, the more the polishing speed of ruthenium is increased under the identical pressure.

In more detail, the slurry containing about 2 wt % of HNO₃ and about 2 wt % of ceric ammonium nitrate has a polishing rate of about 600 □/min under a polishing pressure of 1 psi; the slurry containing about 2 wt % of HNO₃ and about 6 wt % of ceric ammonium nitrate has a polishing rate of about 1200 □/min under a polishing pressure of 1 psi; the slurry containing about 2 wt % of HNO₃ and about 10 wt % of ceric ammonium nitrate has a polishing rate of about 1400 □/min under a polishing pressure of 1 psi; the slurry containing about 6 wt % of HNO₃ and about 2 wt % of ceric ammonium nitrate has a polishing rate of about 1050 □/min under a polishing pressure of 1 psi; and the slurry containing about 10 wt % of HNO₃ and about 2 wt % of ceric ammonium nitrate has a polishing rate of about 1200 □/min under a polishing pressure of 1 psi.

The slurry containing about 2 wt % of HNO₃ and about 2 wt % of ceric ammonium nitrate has a polishing rate of about 1000 □/min under a polishing pressure of 4 psi, the disclosed slurry obtains a polishing rate over 1000 □/min even under a polishing pressure of 1 psi, by slightly increasing a content of HNO₃ and ceric ammonium nitrate.

However, when HNO₃ and ceric ammonium nitrate are used in an amount over 10% by weight of the slurry, the slurry is not stabilized, and a polishing property of a pattern wafer is deteriorated. Accordingly, the content of HNO₃ and ceric ammonium nitrate should be maintained from about 1 to about 10% by weight of the slurry. In addition, the process should be performed under a low polishing pressure to improve the polishing property of the pattern wafer.

The abrasive is used to improve a mechanical operation of the slurry. In the disclosure, CeO₂, ZrO₂ or Al₂O₃ having a grain size below or about 1 μm is used as the abrasive to minimize scratches.

Moreover, the disclosed slurry contains a buffer solution to constantly maintain pH. Here, a mixed solution of organic acid and organic acid salt (1:1), preferably acetic acid and acetic acid salt (1:1) is used as the buffer solution.

As described above, the disclosed slurry has strong acidity and reduces adhesion and density of ruthenium atoms by eroding or melting the surface of ruthenium. Therefore, a chemical property of ruthenium is so varied that ruthenium can be easily polished according to the CMP process.

That is, a mixture of HNO₃ and ceric ammonium nitrate added in the slurry increases an erosion and melting speed of ruthenium, to improve the polishing speed of ruthenium.

A method for preparing the CMP slurry for ruthenium will now be described. CeO₂, ZrO₂ or Al₂O₃ which is an abrasive is added to distilled water. Here, CeO₂, ZrO₂ or Al₂O₃ is added in a stirring speed of about 10000 rpm so that abrasive particles can not be agglomerated. Thereafter, HNO₃ and ceric ammonium nitrate are added thereto. The resulting mixture is stirred for about 30 minutes so that it can be completely mixed and stabilized. Therefore, the disclosed slurry is prepared. Here, the abrasive is used in an amount of from about 1 to about 5% by weight of the slurry, and HNO₃ and ceric ammonium nitrate are used in an amount of from about 1 to about 10% by weight of the slurry.

In addition, another aspect of the present invention provides a CMP process using the CMP slurry for ruthenium.

The CMP process of the present invention, namely a method for forming a ruthenium pattern includes the steps of:

(a) preparing a semiconductor substrate where a ruthenium film or ruthenium alloy film is formed; and

(b) patterning the ruthenium film or ruthenium alloy film according to the CMP process using the CMP slurry composition for ruthenium.

The semiconductor substrate where the ruthenium film or ruthenium alloy film is formed is pressure-adhered to a polishing pad formed on a rotary table of a CMP system. The slurry is supplied to an interface of the polishing pad and the ruthenium film or ruthenium alloy film, thus performing the CMP process. In the CMP process, a polishing pressure ranges from about 1 to about 3 psi, a table revolution number of a rotary type system ranges from about 10 to about 80 rpm, and a table movement speed of a linear type system ranges from about 100 to about 600 fpm in consideration of the polishing speed of ruthenium and the polishing property of the sacrificial insulating film and the pattern wafer. An end-point detector is used to sense a time point of exposing the sacrificial insulating film.

The exposure time of the sacrificial insulating film is sensed by using the end-point detector, and thus the ruthenium film or ruthenium alloy film is not more polished than the sacrificial insulating film, thereby preventing the dishing phenomenon and the erosion of the peripheral sacrificial insulating film.

A semiconductor device where ruthenium is patterned by using the CMP slurry for ruthenium will now be explained with reference to the accompanying drawings.

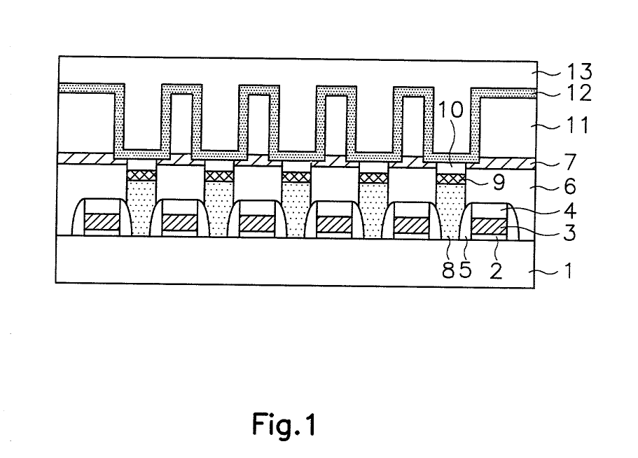

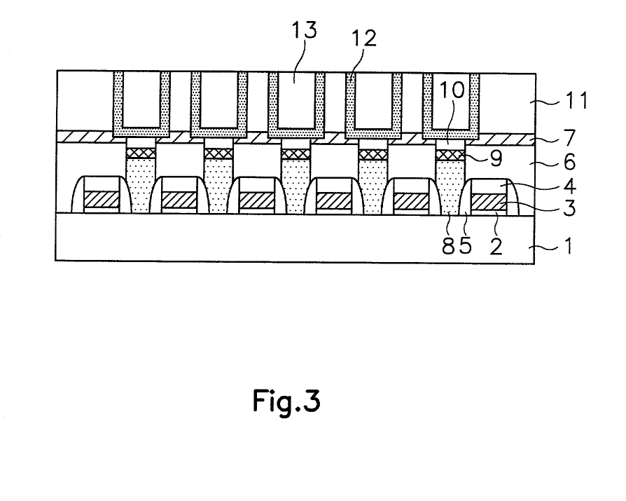

FIG. 3 is a cross-sectional diagram illustrating the semiconductor device where ruthenium is patterned by using the disclosed slurry. The CMP process is performed on the ruthenium film 12 of the capacitor of FIG. 1, by employing the disclosed slurry.

Referring to FIG. 3, when the CMP process is carried out in the process conditions of the present invention, defect generation on the sacrificial insulating film pattern 11 and separation of the ruthenium film 12 are prevented to improve the polishing property.

That is, when the CMP process is performed under a minimum polishing pressure of from about 1 to about 3 psi which is generally allowable in any system, the ruthenium film 12 is closely adhered to the sacrificial insulating film pattern 11, and defects and scratches are prevented.

In addition, when ruthenium is polished according to the CMP process using the slurry of the present invention, a slurry for the sacrificial insulating film is not required, and ruthenium is polished according to an one-step process.

A method for manufacturing a semiconductor device by patterning ruthenium by using the CMP slurry for ruthenium.

The method for manufacturing the semiconductor device includes:

(a) sequentially stacking an interlayer insulating film 6 and silicon nitride 7 on a semiconductor substrate 1 having a predetermined lower structure 2, 3, 4 and 5;

(b) forming a contact hole by exposing a presumed capacitor contact region of the substrate by performing a photolithography process on the resultant structure;

(c) forming a contact plug 8, 9 and 10 in the contact hole;

(d) stacking a sacrificial insulating film on the resultant structure;

(e) forming a sacrificial insulating film pattern 11 by exposing the contact plug by patterning the sacrificial insulating film;

(f) depositing a ruthenium film 12 on the resultant structure;

(g) forming a sacrificial photoresist film pattern 13 by coating a sacrificial photoresist film on the resultant structure and performing a CMP process using the ruthenium film 12 as an etch barrier film; and

(h) forming a lower electrode by patterning the ruthenium film 12 by performing a CMP process using the sacrificial insulating film pattern 11 as an etch barrier film on the resultant structure by using the disclosed slurry composition.

As illustrated in FIG. 3, a gate oxide film 2, a gate electrode 3 and a mask insulating film 4 are formed on the semiconductor substrate 1 having the predetermined lower structure in step (a), and an oxide film spacer 5 is formed at the sidewalls of the resultant structure. The contact plug of step (c) includes a stacked layers of polysilicon 8, TiSi₂ 9 and TiAlN 10. The sacrificial insulating film of step (d) includes an oxide film or oxide nitride film.

The sacrificial insulating film is removed, and a dielectric film and an upper electrode are sequentially formed on the resultant structure, thereby finishing fabrication of the capacitor.

Preferably, the dielectric film is a BST film.

In addition, another aspect of the disclosure provides a semiconductor device manufactured according to the method described above.

The disclosed slurry, processes and methods will now be described by referring to the examples below, which are not intended to be limiting.

### I. PREPARATION OF SLURRY

### Example 1

CeO₂ having a grain size below 1 μm was added to 10 l of distilled water. Here, CeO₂ was added in a stirring speed of about 10000 rpm so that particles cannot be agglomerated. Thereafter, HNO₃ and ceric ammonium nitrate were added thereto. The resulting mixture was stirred for about 30 minutes so that it could be completely mixed and stabilized. Therefore, the disclosed slurry was prepared. Here, CeO₂ was used in an amount of 1% by weight of the slurry, and HNO₃ and ceric ammonium nitrate were used in an amount of 2% by weight of the slurry, respectively.

### Example 2

The procedure of Example 1 was repeated but using 6 wt % of ceric ammonium nitrate, instead of using 2 wt % of ceric ammonium nitrate.

### Example 3

The procedure of Example 1 was repeated but using 10 wt % of ceric ammonium nitrate, instead of using 2 wt % of ceric ammonium nitrate.

### Example 4

The procedure of Example 1 was repeated but using 6 wt % of HNO₃, instead of using 2 wt % of HNO₃.

### Example 5

The procedure of Example 1 was repeated but using 10 wt % of HNO₃, instead of using 2 wt % of HNO₃.

### II. CMP PROCESS USING SLURRY

### Example 6

A table revolution number and a wafer revolution number were respectively set up to be 20 rpm and 80 rpm, by using a rotary type system. Here, the CMP process was performed on the ruthenium film under a polishing pressure of 1 psi by using the slurry prepared in Example 1 (polishing rate is about 600 □/min).

An end-point detector is used to sense a time point of exposing the sacrificial insulating film.

### Example 7

The procedure of Example 6 was repeated but using the slurry prepared in Example 2, instead of using the slurry prepared in Example 1 (polishing rate is about 1200 □/min).

### Example 8

The procedure of Example 6 was repeated but using the slurry prepared in Example 3, instead of using the slurry prepared in Example 1 (polishing rate is about 1400 □/min).

### Example 9

The procedure of Example 6 was repeated but using the slurry prepared in Example 4, instead of using the slurry prepared in Example 1 (polishing rate is about 1050 □/min).

### Example 10

The procedure of Example 6 was repeated but using the slurry prepared in Example 5, instead of using the slurry prepared in Example 1 (polishing rate is about 1200 □/min).

### Example 11

A table movement speed and a wafer revolution number were respectively set up to be 500 fpm and 20 rpm, by using a linear type system. Here, the CMP process was performed on the ruthenium film under a polishing pressure of 1.5 psi by using the slurry prepared in Example 1 (polishing rate is about 1000 □/min).

### Comparative Example 1

A table revolution number and a wafer revolution number were respectively set up to be 20 rpm and 80 rpm, by using a rotary type system. Here, the CMP process was performed on the ruthenium film under a polishing pressure of 4 psi by using a slurry for tungsten (SSW2000 slurry of CABOT) (polishing rate is about 10 □/min).

### Comparative Example 2

A table revolution number and a wafer revolution number were respectively set up to be 20 rpm and 80 rpm, by using a rotary type system. Here, the CMP process was performed on the ruthenium film under a polishing pressure of 4 psi by using a slurry for aluminum (EPA5680 slurry of CABOT) (polishing rate is about 300 □/min).

In accordance with the disclosure, HNO₃ and ceric ammonium nitrate are added to distilled water to prepare the slurry composition. However, other additives may be further added. Moreover, HNO₃ and ceric ammonium nitrate may be added to the general slurry composition.

As discussed earlier, in accordance with the disclosure, the CMP process is performed by using the slurry containing ceric ammonium nitrate, thereby improving the polishing speed of ruthenium under a low polishing pressure. In addition, the CMP process is performed according to an one-step process by using one kind of slurry. As a result, defects on the insulating film are reduced and the polishing property is improved, thereby simplifying the CMP process.

Furthermore, a process margin and a process yield are improved due to the simplified CMP process.

What is claimed:

1. A slurry used in a chemical mechanical polishing (CMP) process, the slurry comprising:
ceric ammonium nitrate [(NH₄)₂Ce(NO₃)₆].

2. The slurry according to claim 1 further comprising an abrasive and an acid.

3. The slurry according to claim 2, wherein the ceric ammonium nitrate is present in an amount ranging from about 1 to about 10% by weight of the slurry.

4. The slurry according to claim 2, wherein the acid is selected from the group consisting of HNO₃, H₂SO₄, HCl, H₃PO₄, and mixtures thereof.

5. The slurry according to claim 2, wherein the acid is HNO₃ and is present in an amount ranging from about 1 to about 10% by weight of the slurry.

6. The slurry according to claim 2, wherein the abrasive is selected from the group consisting of CeO₂, ZrO₂, Al₂O₃ and mixtures thereof.

7. The slurry according to claim 2, wherein a grain size of the abrasive is less than 1 μm.

8. The slurry according to claim 2, wherein the abrasive is used in an amount ranging from about 1 to about 5% by weight of the slurry.

9. The slurry according to claim 2, wherein a pH of the composition ranges from about 1 to about 7.

10. The slurry according to claim 2, wherein the pH of the composition ranges from about 1 to about 3.

11. The slurry according to claim 2, further comprising a buffer.

12. The slurry according to claim 11, wherein the buffer comprises a mixed solution of approximately equal molar amounts of an organic acid and an organic acid salt.

13. The slurry according to claim 12, wherein the buffer comprises a mixed solution of acetic acid and acetic acid salt.

14. A method for forming a ruthenium pattern, the method comprising:
(a) preparing a semiconductor substrate where a ruthenium film or ruthenium alloy film is formed; and
(b) patterning the ruthenium film or ruthenium alloy film using a CMP process using the slurry of claim 2.

15. The method according to claim 14, wherein step (b) is performed with a polishing pressure ranging from about 1 to about 3 psi.

16. The method according to claim 14, wherein step (b) is performed by using a rotary type CMP system, and a table revolution number ranges from about 10 to about 80 rpm.

17. The method according to claim 14, wherein step (b) is performed in a linear type CMP system where a table movement speed ranges from about 100 to about 600 fpm.

18. A method for manufacturing a semiconductor device, the method comprising:
(a) sequentially stacking an interlayer insulating film and silicon nitride on a semiconductor substrate having a predetermined lower structure that comprises a capacitor contact region;
(b) forming a contact hole by exposing the capacitor contact region of the substrate by performing a photolithography process on the structure produced in step (a);
(c) forming a contact plug in the contact hole;
(d) stacking a sacrificial insulating film on the structure formed in steps (a) through (c);
(e) forming a sacrificial insulating film pattern by exposing the contact plug by patterning the sacrificial insulating film;
(f) depositing a ruthenium film on the structure formed in steps (a) through (e);
(g) forming a sacrificial photoresist film pattern by coating a sacrificial photoresist film on the structure formed in steps (a) through (f) and performing a CMP process using the ruthenium film as an etch barrier film; and
(h) forming a lower electrode by patterning the ruthenium film by performing a CMP process using the sacrificial insulating film pattern as an etch barrier film on the structure formed in steps (a) through (g) by using the CMP slurry composition of claim 2.

19. The method according to claim 18, wherein the contact plug comprises stacked layers of polysilicon, TiSi₂ and TiAlN.

20. The method according to claim 18, wherein the sacrificial insulating film is selected from the group consisting of an oxide film and an oxide nitride film.

21. The method according to claim 18, wherein the sacrificial insulating film pattern is removed after step (h), and a dielectric film and an upper electrode are sequentially formed on the resultant structure.

22. The method according to claim 21, wherein the dielectric film is a (Ba₁₋ₓSrₓ)TiO₃ film.

23. A semiconductor device manufactured according to a method of claim 18.
